(19) United States
(12) Patent Application Publication
(10) Pub. No.: US 2009/0040827 A1
(43) Pub. Date: Feb. 12, 2009

(54) Flash memory device for remapping bad blocks and bad block remapping method

(75) Inventor: Min-Su Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/222,265

(22) Filed: Aug. 6, 2008

(30) Foreign Application Priority Data
Aug. 7, 2007 (KR) 10-2007-0079097

(51) Int. Cl. G11C 16/04; G11C 29/02; G11C 8/00

(52) U.S. Cl. 365/185.09; 365/185.11; 365/200; 365/230.03

(57) ABSTRACT

Provided are a flash memory device and a bad block remapping method thereof. The flash memory device includes: an address storage block detecting whether a block address provided from the outside is identical to an already stored block address, and then generating a repair signal according to a detection result; and an encoder converting the repair signal into a block select signal in order to select the normal memory block.

### PRIORITY STATEMENT

This U.S. non-provisional patent application claims priority under 35 U.S.C. §119 to Korean Patent Application No. 10-2007-0079097, filed on Aug. 7, 2007, in the Korean Intellectual Property Office (KIPO), the entire contents of which are incorporated herein by reference.

### BACKGROUND

Example embodiments relate to a semiconductor memory device, and more particularly, to a non-volatile memory device and a memory system.

Semiconductor memory devices are generally classified into volatile semiconductor memory devices and non-volatile semiconductor memory devices. The volatile semiconductor memory devices have a fast read/write speed but lose their stored data if there is no power supply. On the other hand, the non-volatile semiconductor memory devices retain their stored data even when there is no power supply. Therefore, the nonvolatile semiconductor memory devices are used to store data that should be retained regardless of power supply. Examples of the non-volatile semiconductor memory devices are a mask read-only memory (MROM), a programmable read-only memory (PROM), an erasable programmable read-only memory (EPROM), and an electrically erasable programmable read-only memory (EEPROM).

In general, the MROM, the PROM, and the EPROM may not easily erase and write data in itself, such that a general user may experience difficulties to update its memory contents. On the contrary, because the EEPROM may relatively easily erase and write its data, it becomes widely used in system programming for continuous updating and also auxiliary memory devices. Especially, a flash EEPROM (hereinafter, referred to as a flash memory) has a higher degree of integration than a conventional EEPROM, such that it is advantageous for a high capacity auxiliary memory device. A NAND-type flash memory (hereinafter, referred to as a NAND flash memory) has a higher degree of integration than other flash memories.

A flash memory device is an integrated circuit capable of reading its stored information if required. The flash memory device includes a plurality of rewritable memory cells. Each of the memory cells stores 1-bit data or multi-bit data. Flash memory devices are becoming more highly functional as their integration, capacities, and chip sizes increase. The above trends, however, are accompanied by reductions of circuit line widths and increases in the number of manufacturing processes and overall complexity. These limitations are main factors that reduce the yields of chips. To resolve the above limitations, the flash memory device is required to include an extra redundant memory cell for replacing a defective memory cell. Additionally, the flash memory device is required to include various elements for mapping an address of a defective cell into an address of a redundant memory cell. If detecting a bad block during a test, the bad block is replaced with a redundant block. If these bad or defective blocks are properly handled, a flash memory device having bad or defective blocks can be tested as good one. Accordingly, its yield is increased.

However, a fact that the number of redundant blocks in one flash memory device is limited and a situation where the number of detected bad or defective blocks may exceed the number of redundant blocks must be considered. For that reason, a memory manufacturer needs to notify a buyer of the number of allowable unrepaired bad or defective blocks at the beginning of a contract, and then can provide a flash memory device having unrepaired bad or defective blocks. Especially, a NAND flash memory device can normally operate even if there are partially defective memory blocks unlike SRAM and DRAM. In the NAND flash memory device, to prevent bad or defective blocks from being selected, a controller or a user searches a position of a bad block. Thereafter, the bad block is a block having an unrepaired defect.

According to the above technique, a row decoder of a redundant block, which is used to replace a bad block, has a different structure than a row decoder of main blocks. The respectively different structures of row decoders in the same core are accompanied by a great deal of efforts and costs in a layout design. Additionally, there are limitations in utilizing the remaining redundant blocks that are not used to replace bad or defective blocks even after replacement for bad or defective blocks is completed.

### SUMMARY

Example embodiments may provide a method of effectively utilizing a row decoder circuit of a memory block.

Example embodiments may provide flash memory devices for replacing an address of a defective memory block with an address of a normal memory block. The flash memory devices may include: an address storage block detecting whether a block address provided from the outside is identical to an already stored block address, and then generating a repair signal according to a detection result; and an encoder converting the repair signal into a block select signal in order to select the normal memory block.

According to example embodiments, the flash memory devices may further include: a disable circuit generating a disable signal in response to the repair signal; and a pre-decoder generating a block select signal to prevent the detective memory block from being selected in response to the disable signal.

According to example embodiments, the normal memory block and the defective memory block may be respectively selected or prevented according to block row decoders having the same structure.

According to example embodiments, the address storage block may store a block address of the normal memory block when an address of the detective memory block is not stored.

Flash memory devices according to example embodiments may include a plurality of main memory blocks and a plurality of redundant memory blocks, the redundant memory blocks being replaced with a defective memory block in the main memory blocks. According to example embodiments, the flash memory device may further include a plurality of first row decoders corresponding to the main memory blocks, respectively, one of the first row decoders being activated in response to a first block select signal; a plurality of second row decoders corresponding to the redundant memory blocks, one of the second row decoders being selected in response to a second block select signal; an address storage block detecting whether a block address provided from the outside is identical to an already stored block address, and then generating a repair signal according to a detection result; and an encoder converting the repair signal to the second block select signal through encoding, wherein the second row decoders and the first row decoders have the same circuit structure.

According to example embodiments, the already stored block address may include a block address of the defective memory block.

According to example embodiments, the already stored block address may include a block address of the redundant memory block.

According to example embodiments, the block address of the redundant memory block may be allocated being continuous from the block address of the main memory block.

According to example embodiments, the flash memory devices may further include: a disable circuit generating a disable signal in response to the repair signal; and a pre-decoder generating the first block select signal in response to the disable signal to prevent the defective memory block from being selected.

Flash memory devices according to example embodiments may include: a cell array including first memory blocks and second memory blocks, the second memory blocks being replaced with a defective block in the first memory blocks; first row decoders selecting the first memory blocks; second row decoders having the same circuit structure as the first row decoders and selecting the second memory blocks; an address storage block storing an address of the defective block and generating a repair signal corresponding to one of the second row decoders if an external address corresponds to the defective block; and an encoder encoding the repair signal and generating a block select signal to select one of the second row decoders.

According to example embodiments, each of the second row decoders may include: a detection unit detecting whether the block select signal is activated or not; a switch controller switching an output from the detection unit into a high voltage; and a high voltage switch terminal providing a select signal to a corresponding one of the second memory blocks in response to an output of the switch controller.

According to example embodiments, the address storage block may include a plurality of block address storage circuits corresponding to the second row decoders, respectively.

According to example embodiments, an address of the defective block may be stored in a part of the address storage circuits and an original block address of the second memory blocks may be stored in the remaining address storage circuits.

According to example embodiments, the block address storage circuits may include a fuse circuit, an electric fuse circuit, or latch circuits.

According to example embodiments, the flash memory devices may further include: a disable circuit generating a disable signal in response to the repair signal; and a pre-decoder preventing the detective block from being selected in response to the disable signal.

According to example embodiments, repairing methods that may replace a defective memory block with a normal memory block may include: determining whether an inputted block address is identical to an address of the defective memory block; generating a repair signal corresponding to one replaced with the defective memory block among redundant memory blocks if the block address is identical to the address of the defective memory block; and converting the repair signal into a block select signal through encoding in order to select one redundant memory block to be replaced with the defective memory block.

According to example embodiments, a row decoder circuit selecting the defective memory block and a row decoder circuit selecting the redundant memory block may have the same circuit structure.

The methods according to example embodiments may further include preventing the defective memory block from being selected in response to the repair signal.

According to example embodiments, memory systems may include: the above first flash memory device; and a controller exchanging data with the flash memory device.

Memory systems according to example embodiments may include: the above second flash memory device; and a controller exchanging data with the flash memory device.

Memory systems according to example embodiments may include: the above third flash memory device; and a controller exchanging data with the flash memory device.

### BRIEF DESCRIPTION OF THE FIGURES

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram illustrating a flash memory device according to example embodiments;

FIGS. 2A and 2B are circuits illustrating a main decoder and a redundant decoder according to example embodiments;

FIG. 3 is a block diagram illustrating a structure of an address storage block;

FIG. 4A is a circuit diagram illustrating the address storage circuit of FIG. 3 according to example embodiments;

FIG. 4B is a circuit diagram illustrating the address storage circuit of FIG. 3 according to example embodiments;

FIG. 5 is a block diagram illustrating a structure of a redundant block encoder and a block select signal line;

FIG. 6 is a block diagram illustrating a remapping method of a bad block according to example embodiments;

FIG. 7 is a block diagram illustrating a remapping method of a bad block according to example embodiments;

FIG. 8 is a block diagram of a memory system according to example embodiments; and

FIG. 9 is a block diagram of an information processing system according to example embodiments.

### DETAILED DESCRIPTION OF PREFERRED EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Though a NAND flash memory device is used below for illustrating characteristics and functions of example embodiments, example embodiments are not limited thereto.

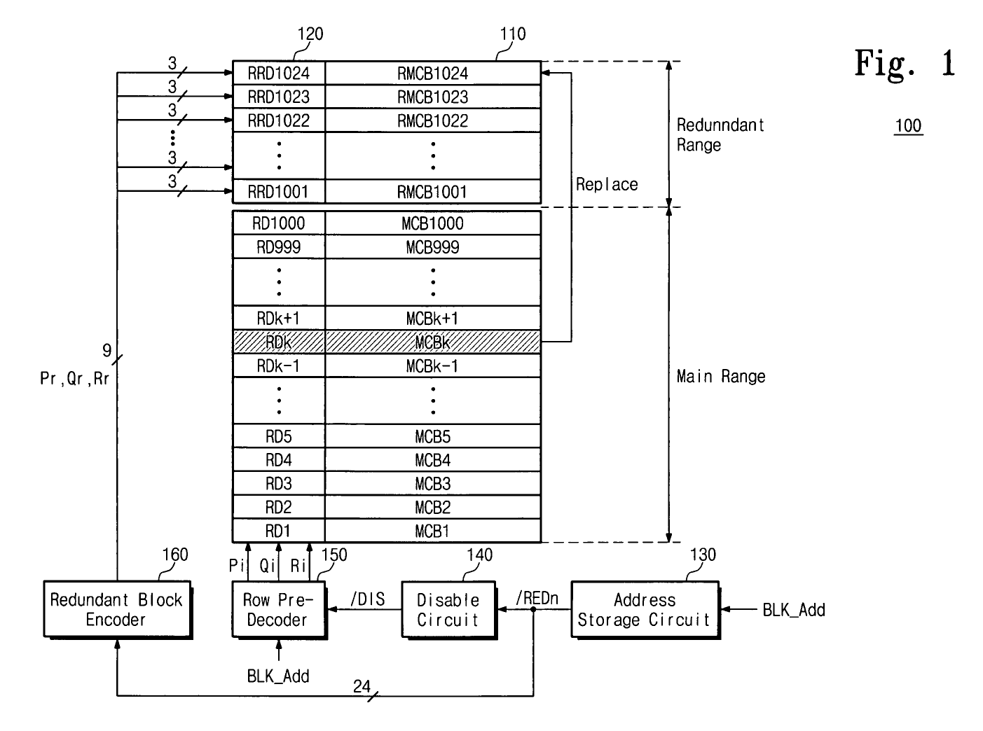

FIG. 1 is a block diagram illustrating a flash memory device 100 including redundant blocks according to example embodiments. Referring to FIG. 1, a flash memory device 100 according to example embodiments may include main decoders RD1 to RD1000 which may correspond to a main range of blocks and redundant decoders RRD1001 to RRD1024 which may correspond to a redundant range of blocks. Main blocks MCB1 to MCB1000 may be connected to the main decoders RD1 to RD1000, respectively. According to example embodiments, the main decoders RD1 to RD1000 and the redundant decoders RRD1001 to RRD1024 may have the same or similar circuit structure. According to example embodiments, each of the main decoders RD1 to RD1000 and the redundant decoders RRD1001 to RRD1024 may include a circuit having the same or similar structure and size. Even with these structures of the decoders, an address switching operation for replacing a bad block may be easily performed by an address storage block 130 and a redundant block encoder 160.

A cell array 110 may be divided into main blocks MCB1 to MCB1000 and redundant blocks RMCB1001 to RMCB1024. The redundant blocks RMCB1001 to RMCB1024 may be memory blocks that are selected instead of bad or defective blocks in the main blocks MCB1 to MCB1000.

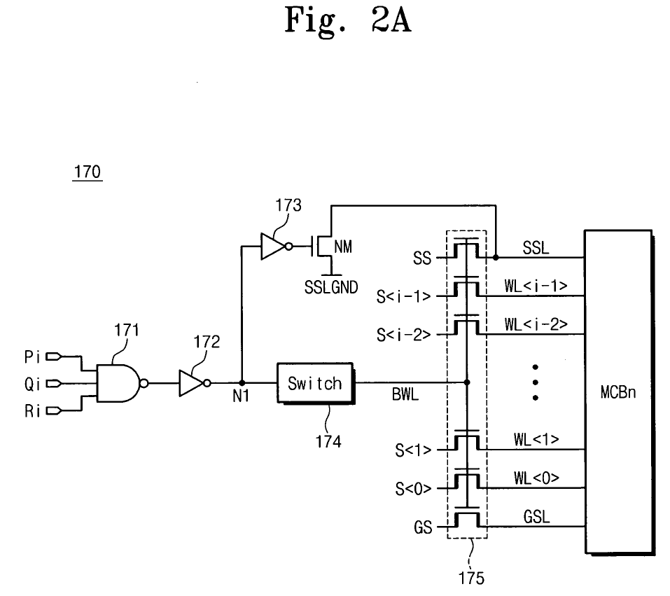

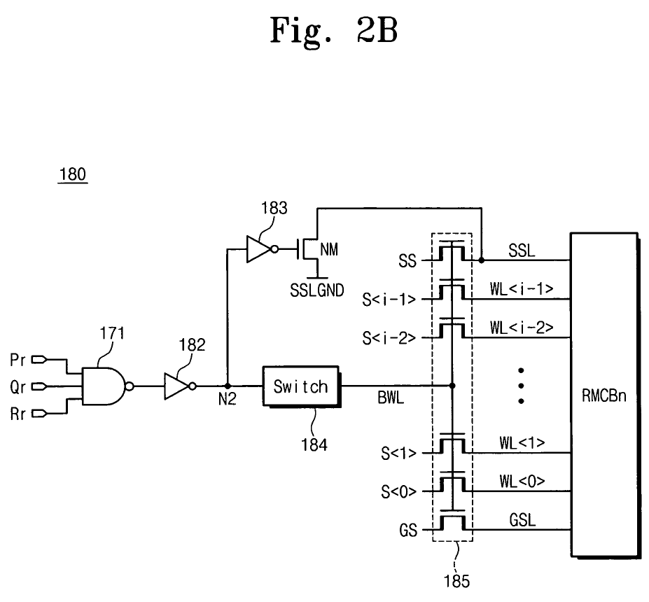

The row decoder 120 may include the row decoder circuits RD1 to RD1000 and RRD1001 to RRD1024 corresponding to the main blocks MCB1 to MCB1000 and the redundant decoders RRD1001 to RRD1024 of the cell array 110, respectively. According to example embodiments, the main blocks MCB1 to MCB1000 may be selected respectively by the main decoder RD1 to RD1000. The redundant blocks RMCB1001 to RMCB1024 may be selected by the corresponding redundant decoders RRD1001 to RRD1024. However, each of the redundant decoders RRD1001 to RRD1024 may be selected by block select signals Pr, Qr, and Rr which may be provided from the block encoder 160. Accordingly, the redundant decoders RRD1001 to RRD1024 may be controlled through the relatively small number of lines. The main decoders RD1 to RD10000 may be selected by block select signals Pi, Qi, and Ri which may be provided from a row pre-decoder 150. Detailed examples of the circuit structure of the main decoders RD1 to RD1000 and the redundant decoders RD1001 to RD1024 will be described with reference to FIGS. 2A and 2B.

The address storage block 130 may store a block address of a bad block in the main blocks MCB1 to MCB1000. The address storage block 130 may detect whether an inputted block address BLK_Add corresponds to a bad block or not. If the inputted block address BLK_Add corresponds to the bad block, the address storage block 130 may outputs a repair signal /REDn which may indicate that the block address BLK_Add is a bad block. The address storage block 130 may be realized with a fuse, an electrical fuse (e-fuse), or register circuits for storing an address of a bad block, or some combination thereof.

The disable circuit 140 may generate a disable signal /DIS to prevent a block decoder, for example RDk, corresponding to a bad block from being selected. When a repair signal /REDn is activated to select one of 24 redundant blocks, the disable circuit 140 may output a disable signal /DIS to prevent a bad block from being selected.

The row pre-decoder 150 may generate block select signals Pi, Qi, and Ri to select a block by decoding the block address BLK_Add. The block select signals Pi, Qi, and Ri, which may be generated by the row pre-decoder 150, may be delivered to the main decoders RD1 to RD1000 to select a corresponding block. However, the row pre-decoder 150 may generate the block select signals Pi, Qi, and Ri to prevent the selecting of a block that corresponds to the inputted block address BLK_Add when the disable signal /DIS is activated.

The redundant block encoder 160 may encode a repair signal /REDn (1≦n≦24 and n is a positive integer), which may be generated from the address storage block 130. The repair signal /REDn, which may be generated from the address storage block 130, may be provided through 24 lines corresponding to the redundant blocks RMCB <1024:1001>. Accordingly, when one of 24 repair singles /RED<24:1> is activated, the redundant block encoder 160 may generate block select signals Pr<2:0>, Qr<2:0>, and Rr<2:0> which may be provided through 9 lines. One of the block select signals Pr<2:0>, Qr<2:0>, and Rr<2:0> may select one of the redundant block decoders RRD<1001: 1024> for activation.

According to example embodiments, with the above-described flash memory device 100, each of the main decoders RD<1000:1> and the redundant decoders RRD<1024:1001> may have the same circuit structure. In response to block select signals Pr<2:0>, Qr<2:0>, and Rr<2:0> which may be generated from the redundant block encoder 160 in response to the repair signal /REDn, the redundant decoders RRD<1024:1001> may be activated. Accordingly, if the number of bad or defective blocks is 10, access to the remaining 14 un-replaced blocks among the redundant blocks RMCB<1001:1024> may be unrestricted. Additionally, since each of the main decoders RD<1000:1> and the redundant decoders RRD<1024:1001> may have the same structure, chip area may be decreased and a layout may be easily designed.

Below, an example where the number of redundant blocks is 24 is described, but example embodiments are not limited thereto. It is apparent to those skilled in the art that the number of redundant blocks is merely a number for simple description and also the number may vary if necessary. Hereinafter, under the assumption that the numbers of redundant blocks and redundant decoders are 24, respectively, functions and operations of general components will be described.

FIGS. 2A and 2B are circuits illustrating the main decoder RDx and the redundant decoder RRDy FIG. 1. A main decoder 170 of FIG. 2A and a decoder 180 of FIG.2B have the same circuit.

Referring to the main decoder 170 of FIG. 2A, when all block select signals Pi, Qi, and Ri, which may be provided from the row pre-decoder 150, are activated, a first node N1 may be set with a ‘HIGH’ level. A switch NM may be cut off to disable a string selection line SSL. A high voltage switch 174 may amplify a logic value of the first node N1 to a high voltage, and may then deliver the logic value to the block word line BWL. When all the block selection signals Pi, Qi, and Ri are activated, a block word line BWL may be boosted to a high voltage, and all pass gates 175 including high voltage switches may be turned on. Then, select signals SS and GS, which may be generated from a driver circuit (NOT shown) and a word line voltage S<i-1:0>, may be delivered to a main cell block MCBn.

Referring to the redundant decoder 180 of FIG. 2B, if all the block select signal Pr, Qr, and Rr provided from the redundant block encoder 160 are activated, a second node N2 may be set with a ‘HIGH’ level. A switch NM may be cut off to disable the string selection line SSL. The high voltage switch 184 may amplify a voltage corresponding a logic value of the second node N2 to a high voltage, and may then deliver the voltage to the block word line BWL. If all the block select signals Pr, Qr, and Rr are activated, the block word line BWL may be boosted to a high voltage, and all pass gates 185 including high voltage switches may be turned on. Then, select signals SS and GS, which may be generated from a driver circuit (not shown) and a word line voltage S<i-1:0> may be delivered to the redundant block RMCBn.

In a structure of the main decoder 170 of FIG. 2A and the redundant decoder 180 of FIG. 2B, a memory block may be selected using the same control method. Accordingly, the main decoder 170 and the redundant decoder 180 may be manufactured with the same size and lay out structure.

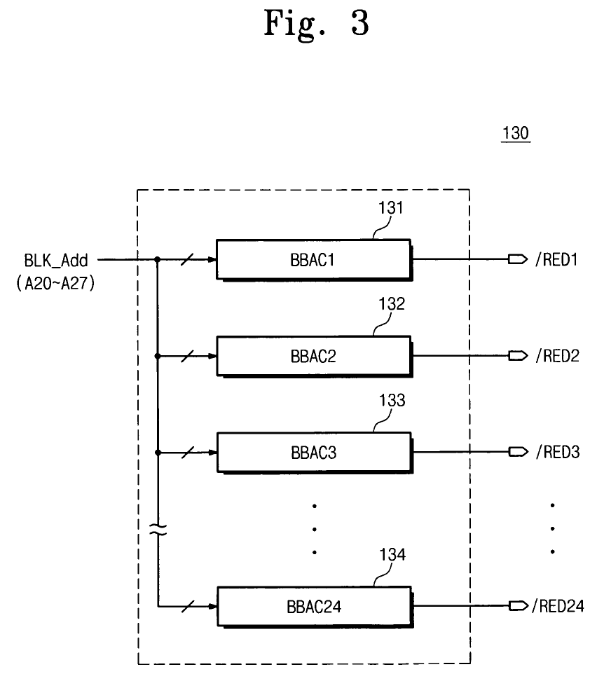

FIG. 3 is a block diagram illustrating a structure of the address storage block 130 according to example embodiments. Referring to FIG. 3, the address storage block 130 may determine whether a block address BLK_Add provided from the external is identical to an address of a bad block. Then, the address storage block 130 may activate one of repair signals /REP<24:1> to select a redundant block to replace the bad block. For example, a block address corresponding to A<27:20> among address bits may be an 8-bit block address. Once the block address A<27:20> of an 8-bit is inputted, it may be simultaneously inputted to 24 address storage circuits BBAC1 to BBAC24. Each of the address storage circuits BBAC1 to BBAC24 may have a block address of a main cell block corresponding to one bad block. If an address of a bad block is inputted, one of the address storage circuits BBAC1 to BBAC24 may generate a repair signal /REDn.

Additionally, according to example embodiments, if the number of bad or defective blocks is less than the number of redundant blocks, the address storage block 130 may provide un-replaced extra redundant blocks to the main blocks MCB1 to MCB1000 as continuous memory blocks. For example, if only two bad or defective blocks exist in the main block, only two block addresses corresponding to the main blocks may be stored in the address storage circuits BBAC1 and BBAC2. The remaining address storage circuits BBAC2 to BBAC24 may store block addresses continuous from the main block addresses. In this case, an access to the redundant blocks may be unrestricted from the external. If an address of un-replaced redundant block is inputted, a corresponding address storage circuit BBACn may generate a repair signal /REDn to select a redundant cell block provided from the external.

According to example embodiments, the setting of the address storage block 130 may allow available memory blocks in a memory device to be used without wasting the memory blocks.

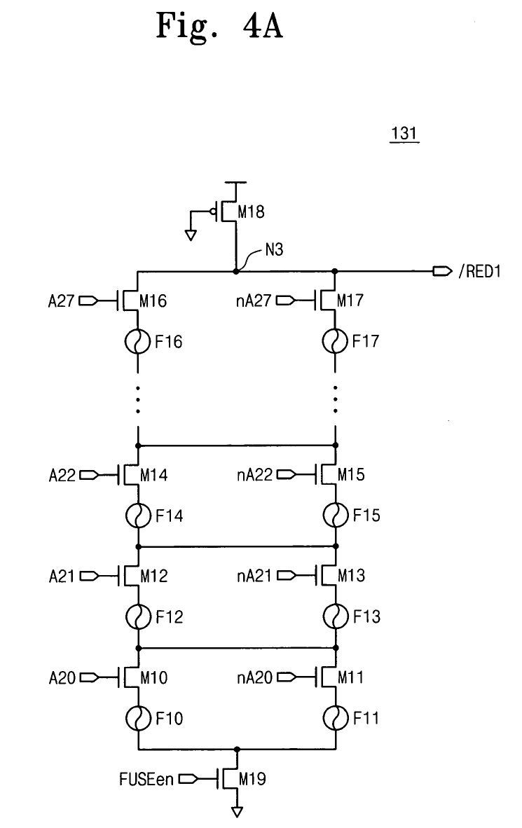

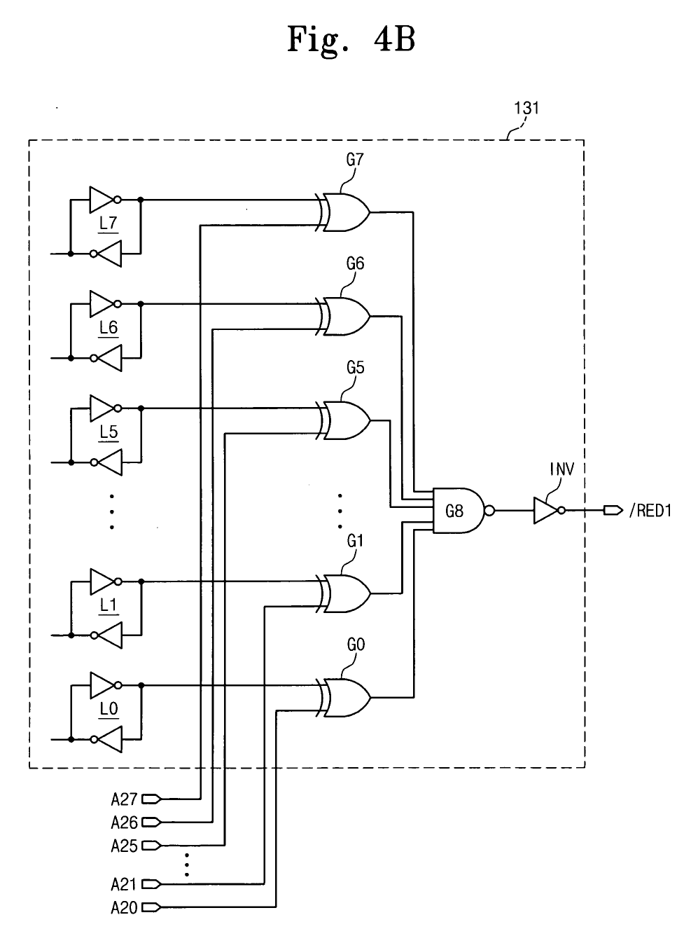

FIGS. 4A and 4B are circuit diagrams of the address storage circuits BBAC1 to BBAC24 of FIG. 3 according to example embodiments. In FIGS. 4A and 4B, only the address storage circuit 131 will be described. However, other address storage circuits, for example address storage circuits 132-134, may have the same structure as those of FIGS. 4A and 4B.

Referring to FIG. 4A, the address storage circuit 131 may have a fuse box form according to example embodiments. Accordingly, a block address A20 to A27 of a bad block may be stored through the programming of fuses F10 to F17. According to a logic value of a bad block address, fuses to be programmed may be determined. That is, the fuses F10 and F11 related to the lowest address bit A20 may be selectively cut off. If a logic value of the lowest address bit A20 is ‘1’, the fuse F11 in the complementary relationship may be cut off. But, a logic value of the lowest address bit A20 is ‘0’, the fuse F10 in the complementary relationship may be cut off. According to these programming methods, the programming of a bad block address progresses up to the highest address A27. According to example embodiments, to store an address of a bad block, the fuses F10 to F17 may be selectively cut off in order to form a current path between a third node N3 and a ground voltage. For example, if an address A20 to A27 of a bad block is ‘11111111”, the fuses F11, F13, F15, and F17 related to complementary address signals nA20 to nA27 of the address bits A20 to A27 may be cut off but the fuses F10, F12, F14, and F16 related to the address signals A20 to A27 may not be cut off. In this case, when only an address of ‘11111111’ is inputted, a current path may be formed between a third node N3 and a ground voltage. Consequently, a repair signal /RED1 may be activated in a low level.

FIG. 4B is a circuit diagram illustrating the address storage circuit 131 including latch circuits and a comparator circuit according to example embodiments. The address storage circuit 131 may include a plurality of latches L0 to L7 in which an address of a bad block may be stored. Address bits corresponding to a bad block may be stored in the latches L0 to L7. When the block address A20 to A27 is inputted, the address bits of a bad block stored in the latches L0 to L7 may be respectively inputted into XOR gates G0 to G7. If address bits of a bad block stored in the latches L0 to L7 are identical to bits of a block address inputted from the outside, an output of the XOR gate may be ‘0’. Accordingly, a repair signal /RED1 outputted via a NAND gate G8 and an inverter INV is activated in a low level.

When an address of a bad block is inputted through the address storage block 130 according to example embodiments, a repair signal /REDn may be generated to replace a bad block. Additionally, addresses of un-replaced remaining extra redundant blocks may be allocated as continuous block addresses in main blocks through the settings of the address storage circuit 131.

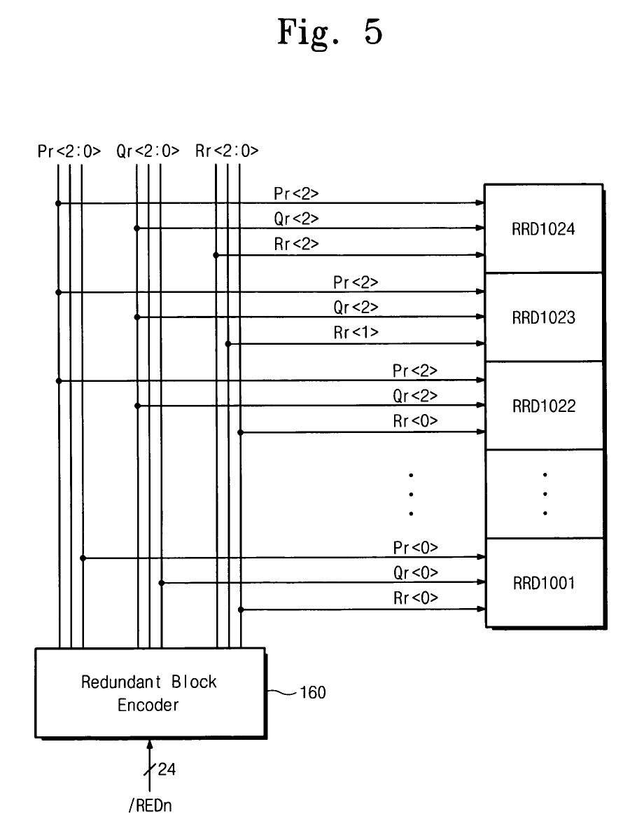

FIG. 5 is a circuit diagram illustrating a selecting method of redundant decoders RRD<1024:1001> through block select signals Pr, Qr, and Rr which may be encoded in a redundant block encoder 160. That is, FIG. 5 illustrates a method of decoding the encoded block select signals Pr, Qr, and Rr. This will be described in more detail below.

A repair signal /REDn corresponding to each of 24 redundant decoders RRD<1024:1001> may be provided to a redundant block encoder 160 through 24 signal lines. The redundant block encoder 160 may generate the block select signal Pr, Qr, and Rr in order to select a redundant decoder RRDn corresponding to one of 24 redundant blocks. At this point, the generated block select signals Pr, Qr, and Rr may each include three lines, for example, Pr<2:0>, Qr<2:0>, and Rr<2:0>, respectively. Accordingly, the repair signal /REDn provided through the 24 lines may be encoded as the block select signals Pr<2:0>, Qr<2:0>, and Rr<2:0> to be provided through 9 signal lines.

Any one of the redundant decoders RRD<1024:1001> may be selected by the block select signals Pr<2:0>, Qr<2:0>, and Rr<2:0>. For example, once the block select signals Pr<2>, Qr<2>, and Rr<2> are activated, the redundant decoder RRD1024 may be selected. Once the block select signals Pr<2>, Qr<2>, and Rr<0> are activated, the redundant decoder RRD1022 is selected. Through the encoding of the block select signal Pr<2:0>, Qr<2:0>, and Rr<2:0>, any one of the 24 redundant decoders RRD<1024:1001> may be selected through the 9 encoded lines.

Accordingly, the redundant decoders RRD<1024:1001> may be selected and activated without a control signal for replacing an additional bad block. By providing the encoded block select signal Pr<2:0>, Qr<2:0>, and Rr<2:0>, the number of signal lines necessary for selecting a redundant decoder may be reduced. If the number of redundant blocks increases, the number of encoded signal lines, for example the block select signal Pr<2:0>, Qr<2:0>, and Rr<2:0>, may also increase.

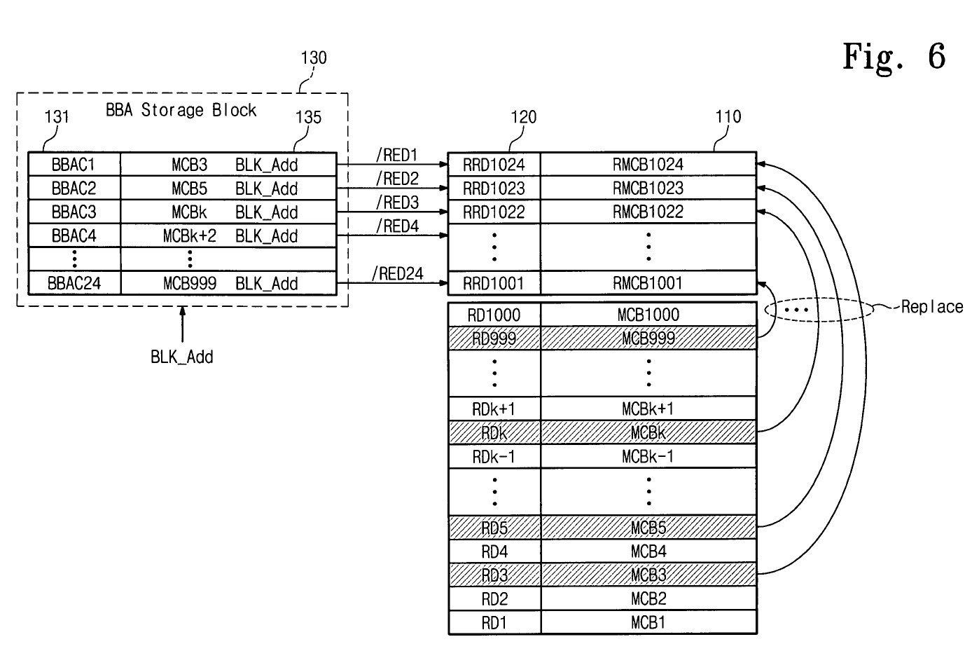

FIG. 6 is a block diagram illustrating a remapping method of a bad block when a bad block address of the address storage block 130 is stored according to example embodiments. FIG. 6 illustrates an example where all memory blocks in a redundant block RMCB<1001:1024> are replaced with bad or defective blocks in the main block MCB<1000:1>. In the example in FIG. 6, the encoding of the repair signal /REDn and the block select signal Pr<2:0>, Qr<2:0>, and Rr<2:0> will not be described.

An address of a bad block may be stored or fuse programmed in all the address storage circuits BBAC1 to BBAC24 of the address storage block 130. Referring to FIG. 6, block addresses 135 of main blocks MCB3, MCB5, MCBk, MCBk+2, . . . , MCB999 corresponding to a bad block may be respectively stored in the address storage circuits BBAC1 to BBAC24. In the example illustrated in FIG. 6, the number of bad or defective blocks in the main block is equal to or greater than the number of redundant blocks. Accordingly, the address storage block 130 may activate repair signals /RED1 to /RED24 in order to replace each of the bad or defective blocks when a block address BLK_Add corresponding to a bad block is provided.

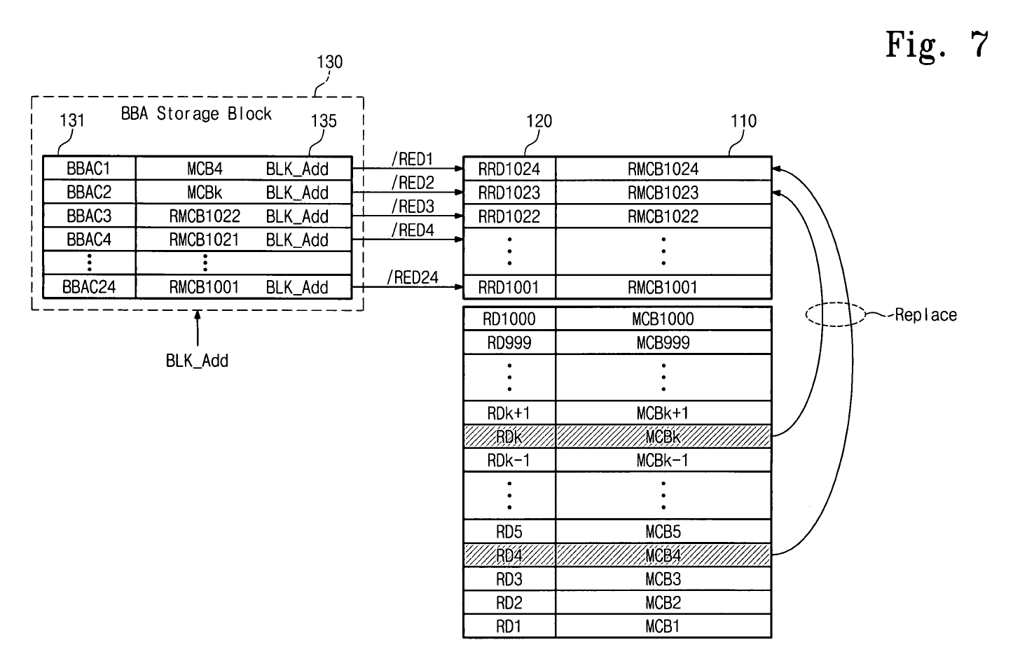

FIG. 7 is a block diagram illustrating an example of using the address storage block 130 to utilize a redundant block when the number of bad or defective blocks is less than the number of redundant blocks according to example embodiments. Like FIG. 6, in the example in FIG. 7, the encoding of the repair signal /REDn and the block select signal Pr<2:0>, Qr<2:0>, and Rr<2:0> of FIG. 5 will not be described. In the example in FIG. 7, the number of bad or defective blocks in a main block is 2. Bad or defective blocks in the main block may correspond to the memory blocks MCB4 and MCBk. Accordingly, block addresses of the bad or defective blocks MCB4 and MCBk may be respectively programmed or fuse programmed into the two address storage circuits BBAC1 and BBAC2 of the address storage block 130.

On the contrary, block addresses continuous from the main block may be programmed or fuse programmed in the remaining address storage circuits BBAC3 to BBAC24. A block address may be inputted in the address storage circuit BBAC24 in order to select the redundant block RMCB1001. A block address may be inputted in the address storage circuit BBAC23 in order to select the redundant block RMCB1002. A block address may be inputted in the address storage circuit BBAC22 in order to select the redundant block RMCB 1003. A block address may be inputted in the address storage circuit BBAC3 in order to select the redundant block RMCB1022. According to example embodiments, original block addresses that redundant blocks have may be written or programmed in the address storage circuits BBAC3 to BBAC24 corresponding to the redundant blocks that are not replaced with bad or defective blocks. Accordingly, the redundant blocks that are not replaced with the bad or defective blocks may have block addresses continuous from the main block. Additionally the redundant blocks may be selected by the block address BLK_Add inputted from the outside. Accordingly, addresses of available redundant memory blocks that are not replaced with bad or defective blocks in the redundant blocks may be required to be provided to the outside or a memory controller. Original block addresses of available redundant blocks may be stored in a specific cell region as initialize data of a flash memory device. The original block addresses of the redundant blocks, which may be available during booting, may be read and then provided to a memory controller or a host, and may then be used for performing an access operation.

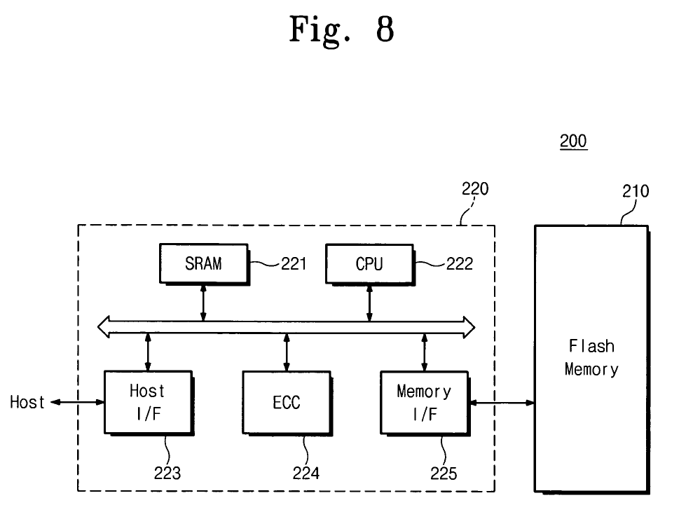

FIG. 8 is a block diagram of a memory system 200 which may include a flash memory device according to example embodiments. Referring to FIG. 8, the memory system 200 for supporting a high capacity storage may include a flash memory device 210 according to example embodiments. The memory system 200 may include a memory controller 220 for controlling general data exchange between a host and the flash memory device 210. Bad or defective blocks of the flash memory device 210 may be replaced with redundant blocks therein. The remaining redundant blocks may be used as available blocks. Information for redundant blocks usable as available blocks may be programmed into a specific region of the flash memory during the setting of the address storage block 130 of FIG. 1. Furthermore, the memory system 200 may not waste the available blocks and may only restrict access to the bad or defective blocks.

SRAM 221 may be used as an operating memory of a central processing unit (CPU) 220. A host interface 223 may include a data exchange protocol of a host connected to the memory system 200. An error correcting code (ECC) block 224 may detect and corrects an error in data read from the multi-bit flash memory device 210. A memory interface 225 may interface with the flash memory device 210. The CPU 222 may perform general control operations for data exchange of the memory controller 220. Although not illustrated in the drawings, it is apparent to those skilled in the art that the memory system 200 may further include ROM (not shown) for storing code data that interface with the host.

According to example embodiments, the memory system 200 may not waste all the available blocks and access may be restricted only to bad or defective blocks in the flash memory device 210.

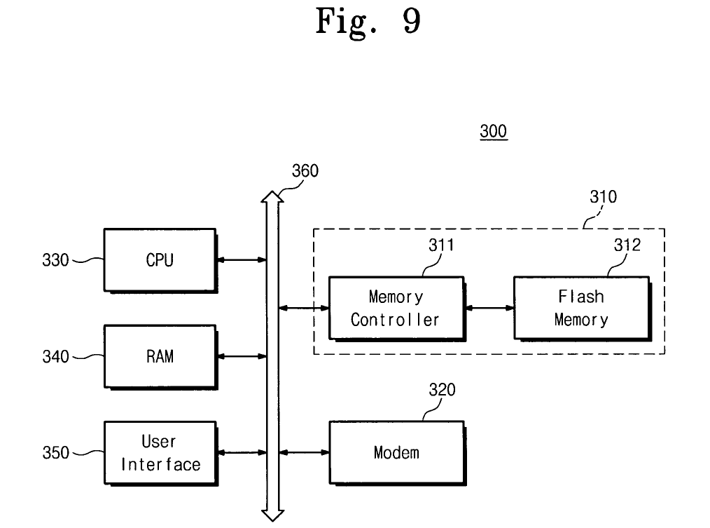

FIG. 9 is a block diagram of an information processing system 300 with a memory system 310. Referring to FIG. 9, the flash memory system 310 according to example embodiments may be mounted on the information processing system 300, for example, a mobile device or desktop computer. The information processing system 300 may include the flash memory system 310, a modem 320, a CPU 330, a RAM 340, and a user interface 350, which may be connected through a system bus 360. The flash memory system 310 may have the same structure as the memory system 200 of FIG. 8. The flash memory system 310 may store data therein, which may be provided through an input/output device (not shown) or processed by the CPU 330.

According to example embodiments, the flash memory system 310 may include a semiconductor disk device (SSD). Although not illustrated in the drawings, it is apparent to those skilled in the art that the information processing system 300 according to example embodiments may further include an application chipset, a camera image processor (CIS), a mobile DRAM, etc.

Moreover, the flash memory device and/or the memory controller according to example embodiments may be mounted through various forms of packages. The packages may include package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP), etc.

With the structure and method according to example embodiments described above, row decoder circuits of memory blocks may be identically formed such that the chip area of a flash memory device may be reduced and the availability of a memory block may be improved.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A flash memory device comprising:
an address storage block detecting whether a block address provided from the outside is identical to an already stored block address, and then generating a repair signal according to a detection result; and
an encoder converting the repair signal into a block select signal.

2. The flash memory device of claim 1, wherein
the flash memory device is for remapping an address of a defective memory block to a normal memory block, and the encoder converts the repair signal into the block select signal in order to select the normal memory block.

3. The flash memory device of claim 2, further comprising:
a disable circuit generating a disable signal in response to the repair signal; and
a pre-decoder generating a block select signal to prevent the defective memory block from being selected in response to the disable signal.

4. The flash memory device of claim 2, wherein the normal memory block and the defective memory block are respectively selected or prevented according to block row decoders, the block row decoders having the same structure.

5. The flash memory device of claim 2, wherein the address storage block stores a block address of the normal memory block when an address of the detective memory block is not stored.

6. The flash memory device of claim 1 further comprising:
a plurality of main memory blocks and a plurality of redundant memory blocks, the addresses of the redundant memory blocks being replaced with the address of a defective memory block in the main memory blocks;
a plurality of first row decoders corresponding to the main memory blocks, respectively, one of the first row decoders being activated in response to a first block select signal; and
a plurality of second row decoders corresponding to the plurality of redundant memory blocks, one of the second row decoders being selected in response to a second block select signal,
wherein the encoder converts the repair signal to the second block select signal through encoding,
and the second row decoders and the first row decoders have the same circuit structure.

7. The flash memory device of claim 6, wherein the already stored block address comprises a block address of the defective memory block.

8. The flash memory device of claim 6, wherein the already stored block address comprises a block address of a redundant memory block from among the plurality of redundant memory blocks.

9. The flash memory device of claim 8, wherein the block address of the redundant memory block is allocated being continuous from the block address of the main memory block.

10. The flash memory device of claim 6, further comprising:
a disable circuit generating a disable signal in response to the repair signal; and
a pre-decoder generating the first block select signal in response to the disable signal to prevent the defective memory block from being selected.

11. The flash memory device of claim 1 further comprising:
a cell array including first memory blocks and second memory blocks, the addresses of the second memory blocks being replaced with the address of a defective block in the first memory blocks;
first row decoders selecting the first memory blocks; and
second row decoders having the same circuit structure as the first row decoders and selecting the second memory blocks,
wherein the encoder encodes the repair signal and generates a block select signal to select one of the second row decoders.

12. The flash memory device of claim 11, wherein each of the second row decoders comprises:
a detection unit detecting whether the block select signal is activated or not;
a switch controller switching an output from the detection unit into a high voltage; and
a high voltage switch terminal providing a select signal to corresponding ones of the second memory blocks in response to an output of the switch controller.

13. The flash memory device of claim 11, wherein the address storage block includes a plurality of block address storage circuits corresponding to the second row decoders, respectively.

14. The flash memory device of claim 13, wherein an address of the defective block is stored in a part of the address storage circuits and an original block address of the second memory blocks is stored in the remaining address storage circuits.

15. The flash memory device of claim 13, wherein the block address storage circuits include at least one of a fuse circuit, an electric fuse circuit, and a latch circuit.

16. The flash memory device of claim 11, further comprising:
a disable circuit generating a disable signal in response to the repair signal; and
a pre-decoder preventing the defective block from being selected, in response to the disable signal.

17. A repairing method that replaces a defective memory block with a normal memory block, the method comprising:
determining whether an inputted block address is identical to an address of the defective memory block;
generating a repair signal corresponding to a redundant memory block, from among a plurality of redundant memory blocks, that replaced the defective memory block if the block address is identical to the address of the defective memory block; and
converting the repair signal into a block select signal through encoding in order to select the redundant memory block that replaced the defective memory block.

18. The method of claim 17, wherein a row decoder circuit selecting the defective memory block and a row decoder circuit selecting the redundant memory block have the same circuit structure.

19. The method of claim 17, further comprising preventing the defective memory block from being selected in response to the repair signal.

20. A memory system comprising:
the flash memory device of claim 2; and
a controller exchanging data with the flash memory device.
